(19) United States
(12) Patent Application Publication
(10) Pub. No.: US 2024/0387751 A1
(43) Pub. Date: Nov. 21, 2024

(54) SEMICONDUCTOR DEVICE AND METHOD FOR MANUFACTURING THE SAME

(71) Applicant: ROHM CO., LTD., Kyoto-shi (JP)

(72) Inventor: Akira SAGAWA, Kyoto-shi (JP)

(73) Assignee: ROHM CO., LTD., Kyoto-shi (JP)

(21) Appl. No.: 18/786,656

(22) Filed: Jul. 29, 2024

Related U.S. Application Data
(63) Continuation of application No. PCT/JP2023/007285, filed on Feb. 28, 2023.

(30) Foreign Application Priority Data
Mar. 24, 2022 (JP) 2022-049157

(51) Int. Cl. H01L 29/872; H01L 23/64; H01L 29/45; H01L 29/47; H01L 29/66

(52) U.S. Cl. CPC H01L 29/8725; H01L 23/647; H01L 29/456; H01L 29/47; H01L 29/66143

(57) ABSTRACT

If a thickness of an Si substrate is dₜ [cm], a resistivity of the Si substrate is ρₛ [Ω·cm], a width of each trench is Wₜ [cm], a thickness of a first electrode formed on a side surface of each trench is tₘ [cm], a resistivity of the first electrode is ρₘ [Ω·cm], an interface resistance between the first electrode and the Si substrate is Rₘₛ [Ω·cm²], an interface resistance between the first electrode and a drift layer is R_{mg} [Ω·cm²], an interface resistance between the Si substrate and the drift layer is R_{sg} [Ω·cm²], a total number of the trenches is n, a length of the Si substrate in the predetermined direction is Wₓ [cm], and α=n·Wₜ/Wₓ, a ratio tₘ/Wₜ of the tₘ with respect to the Wₜ satisfies a condition of a formula (a) shown below.

$${t}_{m} / {W}_{t} > {ρ}_{m} \cdot {d}_{t} / \{ 2 α ( {R}_{m s} + {ρ}_{s} \cdot {d}_{t} + {R}_{sg} ) - 2 {R}_{mg} \} \qquad ( a )$$

### CROSS-REFERENCE TO RELATED APPLICATIONS

The present application is a continuation application of PCT Application No. PCT/JP2023/007285, filed on Feb. 28, 2023, which corresponds to Japanese Patent Application No. 2022-049157 filed on Mar. 24, 2022, with the Japan Patent Office, and the entire disclosures of these applications are incorporated herein by reference.

### TECHNICAL FIELD

The present disclosure relates to a semiconductor device and a method for manufacturing the same.

### BACKGROUND ART

A Schottky barrier diode that uses gallium oxide (Ga₂O₃) is disclosed in Japanese Patent Application Publication No. 2019-179815. The Schottky barrier diode described in Patent Literature 1 includes a semiconductor substrate that is constituted of gallium oxide, a drift layer that is formed on the semiconductor substrate and is constituted of gallium oxide, an anode electrode that is in Schottky contact with the drift layer, and a cathode electrode that is in ohmic contact with the semiconductor substrate.

### BRIEF DESCRIPTION OF DRAWINGS

FIG. 1 is an illustrative plan view for describing the arrangement of a semiconductor device according to a first preferred embodiment of the present disclosure.

FIG. 2 is an illustrative sectional view taken along line II-II of FIG. 1.

FIG. 3 is a partially enlarged sectional view showing a portion A of FIG. 2 in enlarged manner.

FIG. 4 is an illustrative sectional view for describing the arrangement of a semiconductor device according to a comparative example.

FIG. 5A is a sectional view showing a portion of a manufacturing process of the semiconductor device shown in FIG. 1 to FIG. 3 and is a sectional view corresponding to the section plane of FIG. 2.

FIG. 5B is a sectional view showing a step subsequent to that of FIG. 5A.

FIG. 5C is a sectional view showing a step subsequent to that of FIG. 5B.

FIG. 5D is a sectional view showing a step subsequent to that of FIG. 5C.

FIG. 5E is a sectional view showing a step subsequent to that of FIG. 5D.

FIG. 5F is a sectional view showing a step subsequent to that of FIG. 5E.

FIG. 5G is a sectional view showing a step subsequent to that of FIG. 5F.

FIG. 6 is an illustrative sectional view for describing the arrangement of a semiconductor device according to a second preferred embodiment of the present disclosure and is a sectional view corresponding to the section plane of FIG. 2.

### DESCRIPTION OF EMBODIMENTS

A preferred embodiment of the present disclosure provides a semiconductor device including an Si substrate that has a first principal surface and a second principal surface at an opposite side thereto, a drift layer that is disposed on the first principal surface and is constituted of a gallium oxide-based semiconductor layer, a plurality of trenches that are formed by digging in from the second principal surface toward the first principal surface, extend in parallel to each other at equal intervals in a predetermined direction along the second principal surface, and reach the drift layer, and a first electrode that is formed on a side surface and a bottom surface of each trench and is in ohmic contact with the drift layer, and where if a thickness of the Si substrate is dₜ [cm], a resistivity of the Si substrate is ρₛ [Ω·cm], a width of each trench is Wₜ [cm], a thickness of the first electrode formed on the side surface of each trench is tₘ [cm], a resistivity of the first electrode is ρₘ [Ω·cm], an interface resistance between the first electrode and the Si substrate is Rₘₛ [Ω·cm²], an interface resistance between the first electrode and the drift layer is R_{mg} [Ω·cm²], an interface resistance between the Si substrate and the drift layer is R_{sg} [Ω·cm²], a total number of the trenches is n, a length of the Si substrate in the predetermined direction is Wₓ [cm], and (n·Wₜ/Wₓ) is an opening ratio α, a ratio tₘ/Wₜ of the tₘ with respect to the Wₜ satisfies a condition of a formula (a) shown below.

$${t}_{m} / {W}_{t} > {ρ}_{m} \cdot {d}_{t} / \{ 2 α ( {R}_{ms} + {ρ}_{s} \cdot {d}_{t} + {R}_{sg} ) - 2 {R}_{mg} \} \qquad ( a )$$

With this arrangement, a semiconductor device that is inexpensive and high in thermal conductivity can be obtained.

In the preferred embodiment of the present disclosure, an n-type impurity of a first type is doped in the drift layer and a concentration of the n-type impurity of the first type in the drift layer is not less than 4×10¹⁶ cm⁻³ and not more than 1×10¹⁷ cm⁻³.

In the preferred embodiment of the present disclosure, the drift layer includes a first drift layer that is disposed on the first principal surface and a second drift layer that is formed on the first drift layer, an n-type impurity of a first type is doped in each of the first drift layer and the second drift layer, and a concentration of the n-type impurity of the first type in the first drift layer is higher than a concentration of the n-type impurity of the first type in the second drift layer.

In the preferred embodiment of the present disclosure, the concentration of the n-type impurity of the first type in the first drift layer is not less than 1×10¹⁷ cm⁻³ and not more than 1×10¹⁸ cm⁻³ and the concentration of the n-type impurity of the first type in the second drift layer is not less than 1×10¹⁶ cm⁻³ and not more than 1×10¹⁷ cm⁻³.

In the preferred embodiment of the present disclosure, the n-type impurity of the first type is silicon (Si) or tin (Sn).

In the preferred embodiment of the present disclosure, the first principal surface is a (111) plane of the Si substrate.

In the preferred embodiment of the present disclosure, an n-type impurity of a second type is doped in the Si substrate and a concentration of the n-type impurity of the second type is not less than 1×10¹⁶ cm⁻³ and not more than 1×10²⁰ cm⁻³.

In the preferred embodiment of the present disclosure, the n-type impurity of the second type is phosphorus (P).

In the preferred embodiment of the present disclosure, the gallium oxide-based semiconductor layer is constituted of an (Inₓ₁Ga₁₋ₓ₁)₂O₃ (0≤x1<1) layer of an (Alₓ₂Ga₁₋ₓ₂)₂O₃ (0≤x2<1) layer.

In the preferred embodiment of the present disclosure, an insulating film is formed in surface layer portions of the Si substrate at the side surface of each trench.

In the preferred embodiment of the present disclosure, a film thickness of the Si substrate is not less than 50 μm and not more than 1000 μm and a film thickness of the drift layer is not less than 1 μm and not more than 100 μm.

A second electrode that is in Schottky contact with a surface of the drift layer at an opposite side to the Si substrate side is included. In the preferred embodiment of the present

disclosure, the first electrode includes an ohmic metal that is formed on the side surface and the bottom surface of each trench and is in ohmic contact with the drift layer and a first electrode metal that is laminated on the ohmic metal and the second electrode includes a Schottky metal that is in Schottky contact with the surface of the drift layer at the opposite side to the Si substrate side and a second electrode metal that is laminated on the Schottky metal.

A preferred embodiment of the present disclosure provides a method for manufacturing a semiconductor device including a step of forming a drift layer on a first principal surface of an Si substrate that has the first principal surface and a second principal surface at an opposite side thereto, a step of forming a second electrode that is in Schottky contact with a surface of the drift layer at an opposite side to the substrate side, a step of forming, by digging in from the second principal surface toward the first principal surface, a plurality of trenches that extend in parallel to each other at equal intervals in a predetermined direction along the second principal surface and reach the drift layer, and a step of forming, on a side surface and a bottom surface of each trench, a first electrode that is in ohmic contact with the drift layer, and where if a thickness of the Si substrate is dₜ [cm], a resistivity of the Si substrate is ρₛ [Ω·cm], a width of each trench is Wₜ [cm], a thickness of the first electrode formed on the side surface of each trench is tₘ [cm], a resistivity of the first electrode is ρₘ [Ω·cm], an interface resistance between the first electrode and the Si substrate is Rₘₛ [Ω·cm²], an interface resistance between the first electrode and the drift layer is R_{mg} [Ω·cm²], an interface resistance between the Si substrate and the drift layer is R_{sg} [Ω·cm²], a total number of the trenches is n, a length of the Si substrate in the predetermined direction is Wₓ [cm], and (n·Wₜ/Wₓ) is an opening ratio α, a ratio tₘ/Wₜ of the tₘ with respect to the Wₜ satisfies a condition of a formula (a) shown below.

$${t}_{m} / {W}_{t} > {ρ}_{m} \cdot {d}_{t} / \{ 2 α ( {R}_{ms} + {ρ}_{s} \cdot {d}_{t} + {R}_{sg} ) - 2 {R}_{mg} \} \qquad ( a )$$

With this manufacturing method, a semiconductor device that is inexpensive and high in thermal conductivity can be manufactured.

In the following, preferred embodiments of the present disclosure shall be described in detail with reference to the attached drawings.

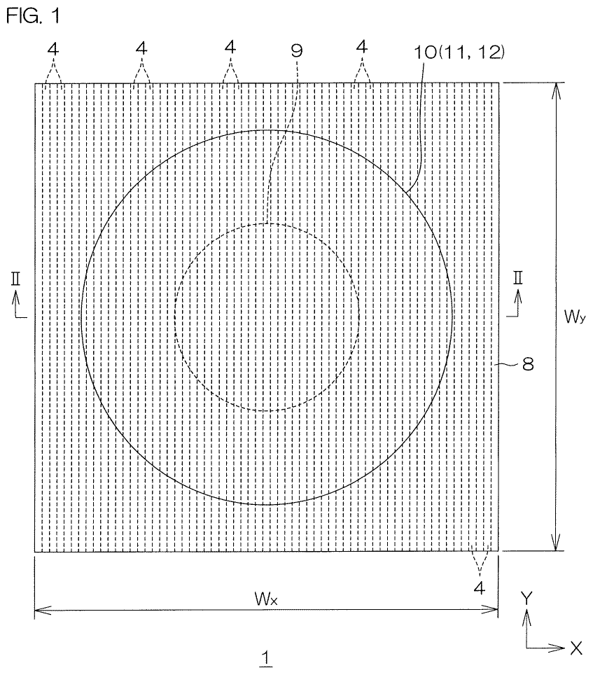

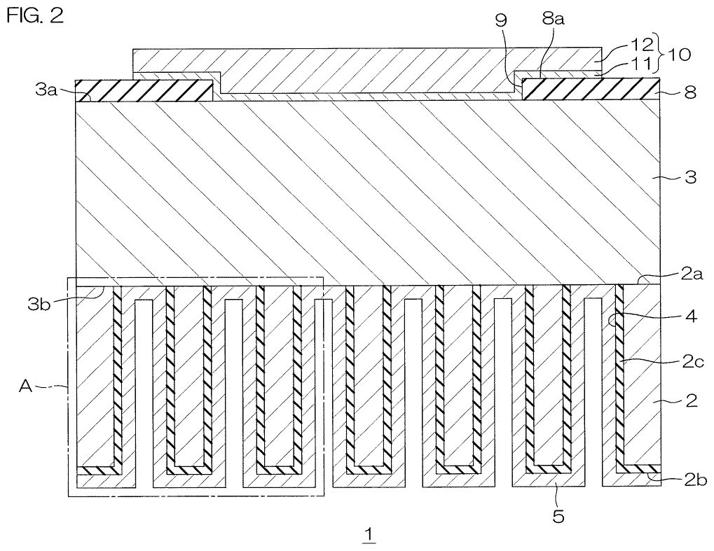

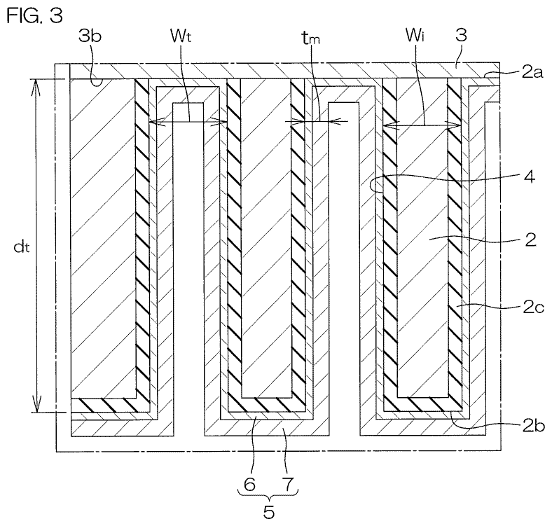

FIG. 1 is an illustrative plan view for describing the arrangement of a semiconductor device according to a first preferred embodiment of the present disclosure. FIG. 2 is an illustrative sectional view taken along line II-II of FIG. 1. FIG. 3 is a partially enlarged sectional view showing a portion A of FIG. 2 in enlarged manner. However, in FIG. 2, a ratio of a width of each trench with respect to a width of the semiconductor device is drawn larger than the actual ratio for convenience of description. Therefore, in FIG. 2, a fewer number of trenches is drawn than actual.

In the following, a right-left direction of the sheet of FIG. 1 shall be referred to as the X direction and an up-down direction of the sheet of FIG. 1 shall be referred to as the Y direction.

A semiconductor device 1 is a Schottky barrier diode. As shown for example in FIG. 1, the semiconductor device 1 is formed in a chip shape that is a quadrilateral shape having two sides parallel to the X direction and two sides parallel to the Y direction in plan view. An X-direction length Wx and a Y-direction length Wy of the semiconductor device 1 in plan view are, for example, approximately several mm. In this preferred embodiment, the X-direction length Wx and the Y-direction length Wy are each 1 mm (1000 μm).

The semiconductor device 1 includes an Si substrate (silicon substrate) 2 that has a first principal surface (front surface) 2a and a second principal surface (rear surface) 2b and is constituted of Si as a main material. Also, the semiconductor device 1 includes a drift layer 3 that is formed on the first principal surface 2a of the Si substrate 2 and is constituted of a gallium oxide (Ga₂O₃) based semiconductor layer. The drift layer 3 has a first principal surface (front surface) 3a and a second principal surface (rear surface) 3b.

An n-type impurity is doped in the Si substrate 2. As the n-type impurity, phosphorus (P), etc., is used. An n-type impurity concentration in the Si substrate 2 may, for example, be not less than 1×10¹⁶ cm⁻³ and not more than 1×10²⁰ cm⁻³. In this preferred embodiment, the n-type impurity concentration in the Si substrate 2 is approximately 1×10¹⁹ cm⁻³. The first principal surface 2a and the second principal surface 2b of the Si substrate 2 are (111) planes. A thickness dₜ of the Si substrate 2 is, for example, not less than 50 μm and not more than 1000 μm. In this preferred embodiment, the thickness dₜ of the Si substrate 2 is 100 μm.

In the Si substrate 2 are formed a plurality of trenches 4 that are formed by digging in from the second principal surface 2b of the Si substrate 2 toward the second principal surface 3b of the drift layer 3, penetrate through the Si substrate 2, and reach the second principal surface 3b of the drift layer 3. The trenches 4 are formed to reduce a resistance of a current path from the second principal surface 3b of the drift layer 3 to a cathode electrode 5 to be described below that is formed on the second principal surface 2b of the Si substrate 2. In this preferred embodiment, bottom surfaces of the trenches 4 are formed by the second principal surface 3b of the drift layer 3.

In this preferred embodiment, the plurality of trenches 4 are disposed at equal intervals in the X direction and extend in parallel to each other in the Y direction. An insulating film 2c that is constituted of a thermal oxide film is formed in surface layer portions of the Si substrate 2 at side surfaces of the trenches 4 and in surface layer portions of the second principal surface 2b. Therefore, in this preferred embodiment, the side surfaces of the trenches 4 are formed by outer surfaces of the insulating film 2c formed in the surface layer portions of the Si substrate 2 at side surfaces of the trenches 4. Also, the second principal surface 2b of the Si substrate 2 is formed by outer surfaces of the insulating film 2c formed in the surface layer portions of the second principal surface 2b of the Si substrate 2.

In this preferred embodiment, a width Wₜ of each trench 4 (hereinafter referred to as the “trench width Wₜ”) is 10 μm and an interval Wᵢ between trenches 4 adjacent in the X direction (hereinafter referred to as the “trench interval Wᵢ”) is 10 μm.

If n is the number of trenches 4, an opening ratio α of the trenches 4 is expressed by α=n·(Wₜ/Wₓ). The trench width Wₜ and the trench interval Wᵢ can be set arbitrarily within a range satisfying a condition of a formula (5) to be described below.

The cathode electrode 5 is formed on entire areas of inner surfaces (bottom surfaces and side surfaces) of the trenches 4 and an entire area of the second principal surface 2b of the Si substrate 2. In this preferred embodiment, a film thickness tₘ of the cathode electrode 5 (to be more detailed, the film thickness tₘ of the cathode electrode 5 formed on the side surfaces of the trenches 4) is 1 μm.

In this preferred embodiment, the cathode electrode 5 is constituted of an ohmic metal 6 that is formed on the entire areas of the inner surfaces of the trenches 4 and the entire area of the second principal surface 2b of the Si substrate 2 and an electrode metal 7 that is laminated on the ohmic metal 6.

The ohmic metal 6 is constituted of a metal (for example, titanium (Ti)) that is in ohmic contact with the second principal surface 3b of the drift layer 3. A film thickness of the ohmic metal 6 is, for example, approximately 0.3 nm to 300 nm. The electrode metal 7 is constituted of gold (Au), copper (Cu), etc. In this preferred embodiment, the electrode metal 7 is constituted of gold (Au). A film thickness of the electrode metal 7 is greater than that of the ohmic metal 6 and is, for example, not less than 1 μm and not more than 100 μm.

Regions of the second principal surface 3b of the drift layer 3 corresponding to the bottom surfaces of the trenches 4 are covered by the cathode electrode 5 (ohmic metal 6). In other words, the regions of the second principal surface 3b of the drift layer 3 corresponding to the bottom surfaces of the trenches 4 are in contact with the cathode electrode 5. Regions of the second principal surface 3b of the drift layer 3 besides the above (regions in which the trenches 4 are not formed) are in contact with the first principal surface 2a of the Si substrate 2. The trench width Wₜ can be defined to be an X-direction length of portions inside the trenches 4 at which the cathode electrode 5 contacts the drift layer 3.

The drift layer 3 is constituted of a gallium oxide-based semiconductor layer such as an (Inₓ₁Ga₁₋ₓ₁)₂O₃ (0≤x1<1) layer, an (Alₓ₂Ga₁₋ₓ₂)₂O₃ (0≤x2<1) layer, etc. In this preferred embodiment, the drift layer 3 is constituted of a gallium oxide (Ga₂O₃) layer that contains an n-type impurity. In this preferred embodiment, the Ga₂O₃ is β-Ga₂O₃. The n-type impurity is doped in the drift layer 3. As the n-type impurity, silicon (Si), tin (Sn), etc., is used. In this preferred embodiment, the n-type impurity is silicon (Si).

An n-type impurity concentration in the drift layer 3 may, for example, be not less than 4×10¹⁶ cm⁻³ and not more than 1×10¹⁷ cm⁻³. In this preferred embodiment, the n-type impurity concentration in the drift layer 3 is approximately 5×10¹⁶ cm⁻³.

A thickness of the drift layer 3 is, for example, not less than 1 μm and not more than 100 μm. In this preferred embodiment, the thickness of the drift layer 3 is 5.5 μm.

A field insulating film 8 constituted, for example, of silicon oxide (SiO₂) is laminated on the first principal surface 3a of the drift layer 3. A thickness of the field insulating film 8 is, for example, not less than 100 nm and preferably not less than 700 nm and not more than 4000 nm. In this preferred embodiment, the thickness of the field insulating film 8 is 500 nm. The field insulating film 8 may be constituted of another insulating material such as silicon nitride (SiN), etc., instead.

An opening 9 that exposes a central portion of the drift layer 3 is formed in the field insulating film 8. In this preferred embodiment, the opening 9 is of a circular shape in plan view. Also, in this preferred embodiment, a diameter of the opening 9 is approximately 400 μm. An anode electrode 10 is formed on the field insulating film 8.

The anode electrode 10 completely fills an interior of the opening 9 of the field insulating film 8 and extends in flange shape to an outside of the opening 9 such as to cover a peripheral edge portion 8a of the field insulating film 8 at the opening 9 from above. That is, the peripheral edge portion 8a of the field insulating film 8 at the opening 9 is sandwiched from both upper and lower sides along its entire circumference by the drift layer 3 and the anode electrode 10. In this preferred embodiment, the anode electrode 10 is of a circular shape in plan view. In this preferred embodiment, a diameter of the anode electrode 10 is 800 μm. In this preferred embodiment, a film thickness of the anode electrode 10 is 1 μm.

In this preferred embodiment, the anode electrode 10 has a multilayer structure (a two-layer structure in this preferred embodiment) of a Schottky metal 11 joined to the drift layer 3 inside the opening 9 of the field insulating film 8 and an electrode metal 12 laminated on the Schottky metal 11.

The Schottky metal 11 is constituted of a metal that forms a Schottky junction by junction with a gallium oxide-based semiconductor layer. In this preferred embodiment, the Schottky metal 11 is constituted of nickel (Ni). The Schottky metal 11 joined to the drift layer 3 forms a Schottky barrier (potential barrier) with the gallium oxide-based semiconductor layer that constitutes the drift layer 3. In this preferred embodiment, a thickness of the Schottky metal 11 is, for example, not less than 0.02 μm and not more than 0.2 μm.

The electrode metal 12 is a portion of the anode electrode 10 that is exposed at a frontmost surface of the semiconductor device 1 and to which a bonding wire, etc., is joined. The electrode metal 12 is constituted of gold (Au), copper (Cu), etc. In this preferred embodiment, the electrode metal 12 is constituted of gold (Au). In this preferred embodiment, a thickness of the electrode metal 12 is greater than that of the Schottky metal 11 and is, for example, not less than 0.5 μm and not more than 5.0 μm.

Here, of the front surface of the drift layer 3, a region in which the Schottky metal 11 is in Schottky contact with the front surface of the drift layer 3 is called an active region and a region surrounding the active region is called an outer peripheral region at times.

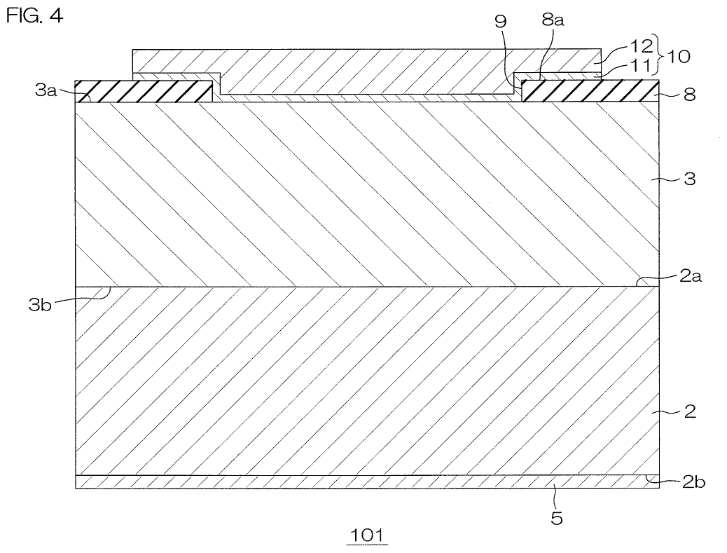

In the following description, a semiconductor device 101 shown in FIG. 4 shall be a comparative example. In FIG. 4, respective portions corresponding to those in FIG. 2 are indicated with the same reference signs attached as in FIG. 2.

In comparison to the semiconductor device 1 of the preferred embodiment shown in FIG. 1 to FIG. 3, the semiconductor device 101 of the comparative example differs in the points that the trenches 4 are not formed and an insulating film is not formed in a surface layer portion of an exposed surface of the Si substrate 2. With the semiconductor device 101 of the comparative example, the second principal surface 2b of the Si substrate 2 is a flat surface because the trenches 4 are not formed. Also, the cathode electrode 5 is formed on the entire area of the second principal surface 2b of the Si substrate 2.

An X-direction length Wₓ and a Y-direction length W_{y} of the semiconductor device 101 of the comparative example are respectively the same as the X-direction length Wₓ and the Y-direction length W_{y} of the semiconductor device 1 of the preferred embodiment. The film thickness dₜ of the Si substrate 2, the film thickness of the drift layer 3, the film thickness of the cathode electrode 5, and the film thickness of the anode electrode 10 in the semiconductor device 101 of the comparative example are respectively the same as the thickness dₜ of the Si substrate 2, the film thickness of the drift layer 3, the film thickness of the cathode electrode 5, and the film thickness of the anode electrode 10 in the semiconductor device 1 of the preferred embodiment.

A resistance R_{wo} [Ω] of a current path from an interface portion between the Si substrate 2 and the drift layer 3 to the cathode electrode 5 on the second principal surface 2b of the Si substrate 2 in the comparative example is expressed by a formula (1) shown below.

$${R}_{wo} [ Ω ] = ( {R}_{ms} + {ρ}_{s} {d}_{t} + {R}_{sg} ) / ( {W}_{x} \cdot {W}_{y} ) \qquad ( 1 )$$

In the formula (1), the units of Wₓ, W_{y}, and dₜ are [cm]. Also, Rₘₛ [Ω·cm²] is an interface resistance between the cathode electrode 5 and the Si substrate 2, ρₛ [Ω·cm] is a resistivity of the Si substrate 2, and R_{sg} [Ω·cm²] is an interface resistance between the Si substrate 2 and the drift layer 3.

The Rₘₛ [Ω·cm²], ρₛ [Ω·cm], and the R_{sg} [Ω·cm²] in the comparative example are respectively the same as the interface resistance Rₘₛ [Ω·cm²] between the cathode electrode 5 and the Si substrate 2, the resistivity ρₛ [Ω·cm] of the Si substrate 2, and the interface resistance R_{sg} [Ω·cm²] between the Si substrate 2 and the drift layer 3 in the semiconductor device 1 of the preferred embodiment.

As shown in a formula (2) below, a resistance R_{wo} [Ω·cm²] of a unit area (1 cm²) is determined by multiplying the right hand side of the formula (1) by (Wₓ·W_{y}).

$${R}_{wo} [ Ω \cdot {cm}^{2} ] = ( {R}_{ms} + {ρ}_{s} {d}_{t} + {R}_{sg} ) \qquad ( 2 )$$

A resistance R_{w} [Ω] of a current path from an interface portion between the cathode electrode 5 and the drift layer 3 to the cathode electrode 5 on the second principal surface 2b of the Si substrate 2 in the preferred embodiment is expressed by a formula (3) shown below.

$${R}_{w} [ Ω ] = ( {ρ}_{m} {d}_{t} + 2 {nt}_{m} {W}_{y} ) + ( {R}_{mg} / α {W}_{x} \cdot {W}_{y} ) = \{ ( {ρ}_{m} {d}_{t} {W}_{t} / 2 {t}_{m} α ) + ( {R}_{mg} / α ) \} / ( {W}_{x} \cdot {W}_{y} ) \qquad ( 3 )$$

In the formula (3), the units of Wₓ, W_{y}, dₜ, and tₘ are [cm]. Also, n is the number of trenches 4, α is the opening ratio (=n·Wₜ/Wₓ), ρₘ [Ω·cm] is the resistivity of the cathode electrode 5, and R_{mg} [Ω·cm²] is an interface resistance between the cathode electrode 5 and the drift layer 3.

As shown in a formula (4) below, a resistance R_{w} [Ω·cm²] of a unit area (1 cm²) is determined by multiplying the right hand side of the formula (3) by (Wₓ·W_{y}).

$${R}_{w} [ Ω \cdot {cm}^{2} ] = ( {ρ}_{m} {d}_{t} {W}_{t} / 2 {t}_{m} α ) + ( {R}_{mg} / α ) \qquad ( 4 )$$

From the formula (2) and the formula (4), a condition by which the resistance R_{w} [Ω·cm²] in the preferred embodiment becomes less than the resistance Rₘₛ [Ω·cm²] in the comparative example is expressed by a formula (5) shown below.

$${t}_{m} / {W}_{t} > ( {ρ}_{m} \cdot {d}_{t} ) / \{ 2 α ( {R}_{ms} + {ρ}_{s} \cdot {d}_{t} + {R}_{sg} ) - 2 {R}_{mg} \} \qquad ( 5 )$$

With the preferred embodiment, the film thickness tₘ of the cathode electrode 5 and the trench width Wₜ are set to satisfy the condition of the formula (5).

An example of values of ρₘ [Ω·cm], ρₛ [Ω·cm], Rₘₛ [Ω·cm²], R_{mg} [Ω·cm²], and R_{sg} [Ω·cm²] and an example of preferable values dₜ [cm], Wᵢ [cm], tₘ [cm], and Wₜ [cm] are as follows.

$${ρ}_{m} = 0.0000012 [ Ω \cdot cm ] \\ {ρ}_{s} = 0.001 [ Ω \cdot cm ] \\ {R}_{ms} = 3 \times 1 {0}^{- 7} [ Ω \cdot {cm}^{2} ]$$

$${R}_{mg} = 5 \times 1 {0}^{- 6} [ Ω \cdot {cm}^{2} ]$$

$${R}_{sg} = 5.8 \times 1 {0}^{- 6} [ Ω \cdot {cm}^{2} ]$$

$${d}_{t} = 0.01 [ cm ] \\ {W}_{i} = 0.0 \; 01 [ cm ]$$

$${t}_{m} = 0.0 \; 001 [ cm ]$$

$${W}_{t} = 0.0 \; 01 [ cm ]$$

With the semiconductor device 1 according to the preferred embodiment, the semiconductor device (Schottky barrier diode) 1 that is inexpensive and high in conductivity can be obtained because the Si substrate 2 is inexpensive and high in conductivity in comparison to a gallium oxide substrate.

Also, with the present embodiment, the resistance of the current path from the second principal surface 3b of the drift layer 3 to the cathode electrode 5 on the second principal surface 2b of the Si substrate 2 can be reduced because the film thickness tₘ of the cathode electrode 5 and the trench width Wₜ are set to satisfy the condition of the formula (5). The semiconductor device 1 of higher thermal conductivity can thereby be obtained.

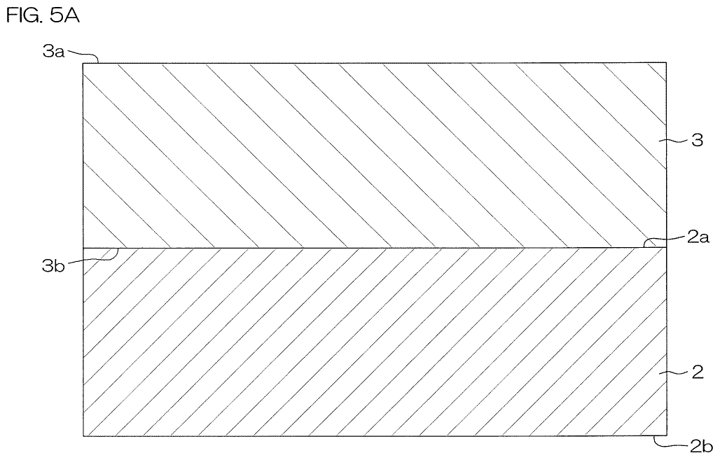

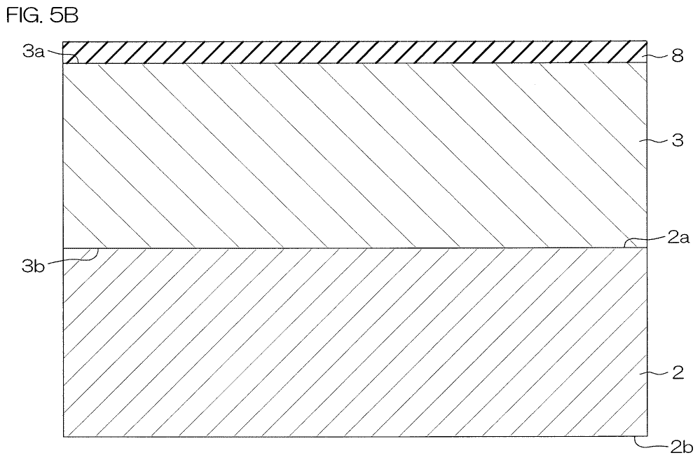

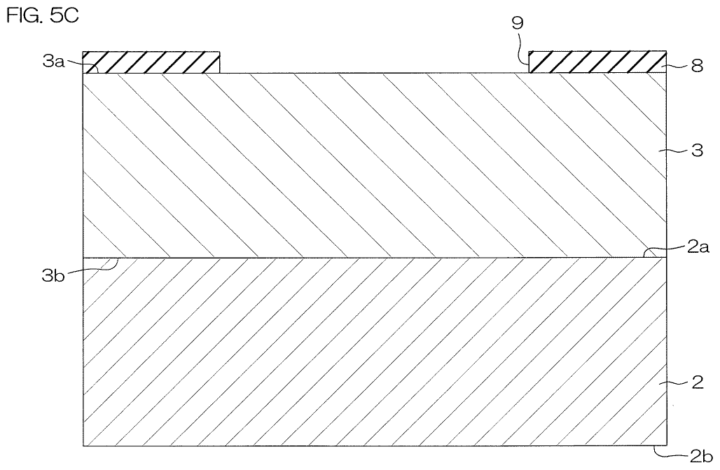

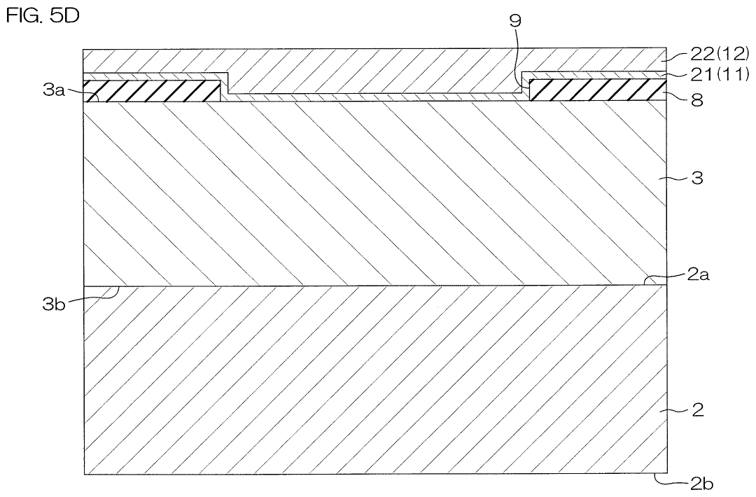

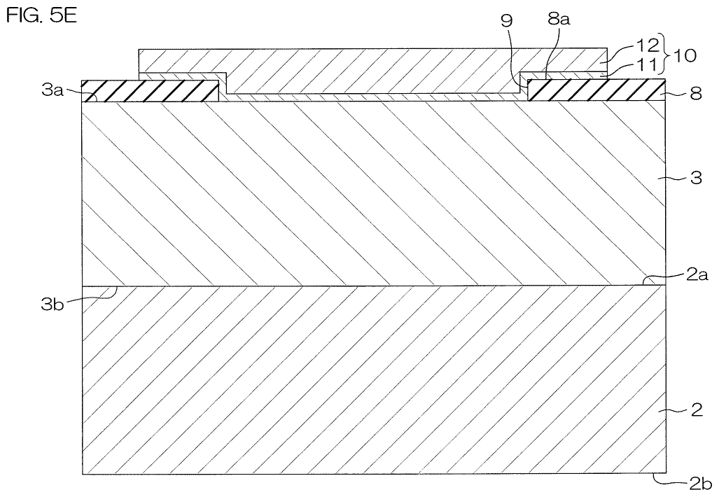

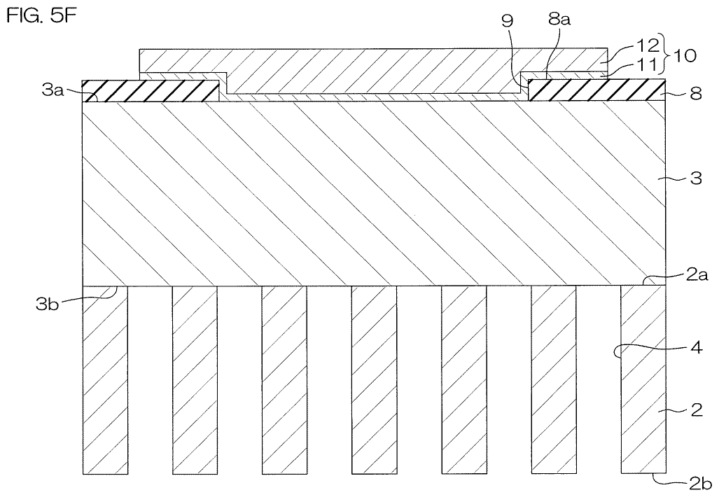

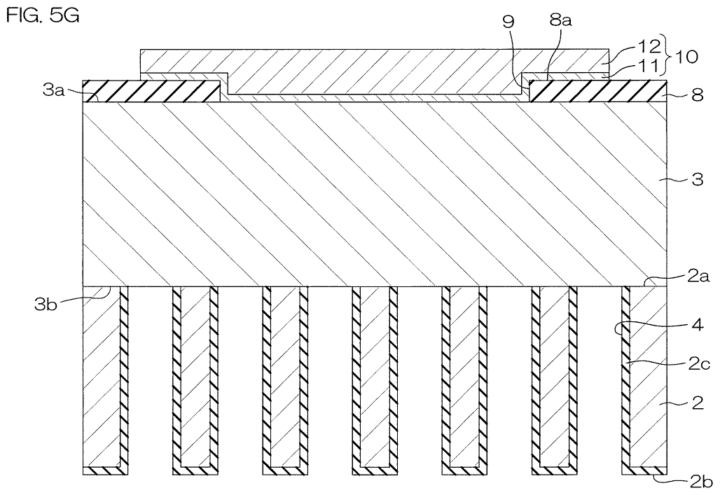

FIG. 5A to FIG. 5G are sectional views showing an example of a manufacturing process of the semiconductor device 1 and are sectional views corresponding to the section plane of FIG. 2.

An n-type silicon wafer (not shown) is prepared as a base substrate of the Si substrate 2. A plurality of element (Schottky barrier diode) regions corresponding to a plurality of the semiconductor devices (Schottky barrier diodes) 1 are arrayed and set in a matrix on a front surface of the silicon wafer. Boundary regions (scribe lines) are provided between adjacent element regions. The boundary regions are regions of band shape having a substantially fixed width, extend in two orthogonal directions, and are formed in a lattice. The plurality of semiconductor devices 1 are obtained by cutting apart the silicon wafer along the boundary regions after performing necessary processes on the silicon wafer.

First, as shown in FIG. 5A, the drift layer 3 constituted of gallium oxide (Ga₂O₃) doped with the n-type impurity is formed on the first principal surface 2a of the n-type Si substrate (n-type silicon wafer) 2, for example, by a CVD (chemical vapor deposition) method such as a hydride vapor epitaxy (HVPE) method.

Next, as shown in FIG. 5B, the field insulating film 8 constituted of silicon oxide (SiO₂) is formed on the first principal surface 3a of the drift layer 3.

Next, as shown in FIG. 5C, the opening 9 that exposes the central portion (active region) of the drift layer 3 is formed by etching the field insulating film 8 using an unillustrated resist pattern prepared by photolithography as a mask.

Next, as shown in FIG. 5D, a material film 21 of the Schottky metal 11 is formed on front surfaces of the drift layer 3 and the field insulating film 8, for example, by a sputtering method. The material film 21 is, for example, a nickel (Ni) layer. After then forming a gold plating seed layer on the material film 21, for example, by a vapor deposition method, a film of gold (Au) is formed on the gold plating seed layer, for example, by a plating method. A material film 22 of the electrode metal 12 is thereby formed on the material film 21.

Next, as shown in FIG. 5E, the electrode metal 12 is formed by patterning the material film 22 by photolithography and etching. Subsequently, the Schottky metal 11 is formed by patterning the material film 21. The Schottky metal 11 is formed such as to cover an entire area of the first principal surface 3a of the drift layer 3 inside the opening 9. The anode electrode 10 constituted of the Schottky metal 11 and the electrode metal 12 is thereby formed.

Next, as shown in FIG. 5F, the plurality of trenches 4 reaching the second principal surface 3b of the drift layer 3 from the second principal surface 2b of the Si substrate 2 is formed in the Si substrate 2 by photolithography and etching.

Next, as shown in FIG. 5G, the insulating film (silicon thermal oxide film) 2c constituted of the thermal oxide film is formed in surface layer portions of an exposed surface of the Si substrate 2, for example, by a thermal oxide method.

Lastly, the cathode electrode 5 is formed on the inner surfaces of the trenches 4 and on the second principal surface 2b of the Si substrate 2. The semiconductor device 1 such as shown in FIG. 1 to FIG. 3 is thereby obtained.

The cathode electrode 5 is formed as follows. First, the ohmic metal 6 is formed by forming a titanium (Ti) layer on the inner surfaces of the trenches 4 and the second principal surface 2b of the Si substrate 2, for example, by a sputtering method. A gold plating seed layer is then formed on the ohmic metal 6, for example, by a vapor deposition method and thereafter, a film of gold (Au) is formed on the gold plating seed layer, for example, by a plating method.

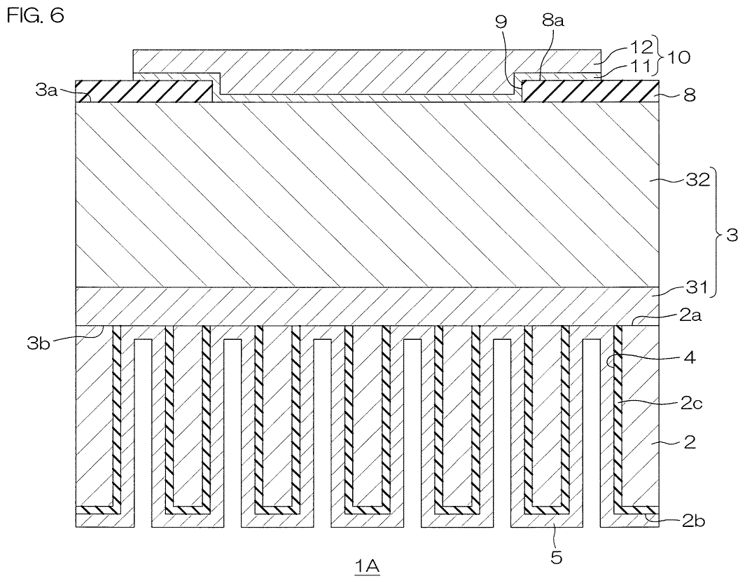

FIG. 6 is an illustrative sectional view for describing the arrangement of a semiconductor device according to a second preferred embodiment of the present disclosure and is a sectional view corresponding to the section plane of FIG. 2. In FIG. 6, respective portions corresponding to those in FIG. 2 are indicated with the same reference signs attached as in FIG. 2. Here, a plan view of a semiconductor device 1A according to the second preferred embodiment is the same as the plan view (FIG. 1) of the semiconductor device 1 according to the first preferred embodiment.

With the semiconductor device 1A according to the second preferred embodiment, the arrangement of the drift layer 3 differs from that of the semiconductor device 1 according to the first preferred embodiment.

With the semiconductor device 1A according to the second preferred embodiment, the drift layer 3 includes a first drift layer 31 that is disposed on the first principal surface 2a of the Si substrate 2 and a second drift layer 32 that is formed on the first drift layer 31. The first drift layer 31 and the second drift layer 32 are each constituted of a gallium oxide-based semiconductor layer such as an (Inₓ₁Ga₁₋ₓ₁)₂O₃ (0≤x1<1) layer, an (Alₓ₂Ga₁₋ₓ₂)₂O₃ (0≤x2<1) layer, etc. In this preferred embodiment, the first drift layer 31 and the second drift layer 32 are each constituted of a gallium oxide (Ga₂O₃) layer that contains an n-type impurity. In this preferred embodiment, the Ga₂O₃ is β-Ga₂O₃. The n-type impurity is doped in the first drift layer 31 and the second drift layer 32. As the n-type impurity, silicon (Si), tin (Sn), etc., is used. In this preferred embodiment, the n-type impurity is silicon (Si).

An n-type impurity concentration in the first drift layer 31 is higher than an n-type impurity concentration in the second drift layer 32. The first drift layer 31 functions as a current diffusion layer.

The n-type impurity concentration in the first drift layer 31 is preferably, for example, not less than 1×10¹⁷ cm⁻³ and not more than 1×10¹⁸ cm⁻³. In this preferred embodiment, the n-type impurity concentration in the first drift layer 31 is approximately 1×10¹⁸ cm⁻³. A thickness of the first drift layer 31 is, for example, not less than 0.1 μm and not more than 10 μm. In this preferred embodiment, the thickness of the first drift layer 31 is approximately 1 μm.

The n-type impurity concentration in the second drift layer 32 is preferably, for example, not less than 1×10¹⁶ cm⁻³ and not more than 1×10¹⁷ cm⁻³. In this preferred embodiment, the n-type impurity concentration in the second drift layer 32 is approximately 5×10¹⁶ cm⁻³. A thickness of the second drift layer 32 is, for example, not less than 1 μm and not more than 100 μm. In this preferred embodiment, the thickness of the second drift layer 32 is approximately 5.5 μm.

Even in the second preferred embodiment, the film thickness tₘ of the cathode electrode 5 and the trench width Wₜ are set to satisfy the condition of the formula (5). Therefore, the same effects as the first preferred embodiment are exhibited by the second preferred embodiment as well.

Also, with the second preferred embodiment, since the drift layer 3 includes the first drift layer 31 that functions as the current diffusion layer, variation of current density in the X direction inside the drift layer 3 can be reduced. A resistance of the drift layer 3 can thereby be reduced.

Although the first and second preferred embodiments of the present disclosure have been described above, the present disclosure can be implemented in yet other preferred embodiments. For example, although in each of the first and second preferred embodiments described above, the insulating film 2c constituted of the thermal oxide film is formed in the surface layer portions of the Si substrate 2 at the side surfaces of the trenches 4 and in the surface layer portions of the second principal surface 2b, the insulating film 2c does not have to be formed.

Also, although in each of the first and second preferred embodiments described above, the anode electrode 10 is of the two-layer structure of the Schottky metal 11 and the electrode metal 12, it may instead be of a single-layer structure or a structure of three or more layers. As the materials of the Schottky metal 11 and the electrode metal 12, appropriate and adequate materials may be selected and used. The thicknesses of the Schottky metal 11 and the electrode metal 12 are an example and appropriate and adequate values may be selected and used. Also, although the planar shape of the anode electrode 10 is a circular shape, it may be a shape other than a circular shape, such as an elliptical shape, polygonal shape, etc.

Also, although in each of the first and second preferred embodiments described above, the cathode electrode 5 is of the two-layer structure of the ohmic metal 6 and the electrode metal 7, it may instead be of a single-layer structure or a structure of three or more layers. As the materials of the ohmic metal 6 and the electrode metal 7, appropriate and adequate materials may be selected and used. The thicknesses of the ohmic metal 6 and the electrode metal 7 are an example and appropriate and adequate values may be selected and used.

While preferred embodiments of the present disclosure have been described in detail above, those are merely specific examples used to clarify the technical contents of the present disclosure, and the present disclosure should not be interpreted as being limited only to those specific examples, and the scope of the present disclosure shall be limited only by the appended claims.

What is claimed is:

1. A semiconductor device comprising:
an Si substrate that has a first principal surface and a second principal surface at an opposite side thereto;
a drift layer that is disposed on the first principal surface and is constituted of a gallium oxide-based semiconductor layer;
a plurality of trenches that are formed by digging in from the second principal surface toward the first principal surface, extend in parallel to each other at equal intervals in a predetermined direction along the second principal surface, and reach the drift layer; and
a first electrode that is formed on a side surface and a bottom surface of each trench and is in ohmic contact with the drift layer; and
wherein if a thickness of the Si substrate is dₜ [cm], a resistivity of the Si substrate is ρₛ [Ω·cm], a width of each trench is Wₜ [cm], a thickness of the first electrode formed on the side surface of each trench is tₘ [cm], a resistivity of the first electrode is ρₘ [Ω·cm], an interface resistance between the first electrode and the Si substrate is Rₘₛ [Ω·cm²], an interface resistance between the first electrode and the drift layer is R_{mg} [Ω·cm²], an interface resistance between the Si substrate and the drift layer is R_{sg} [Ω·cm²], a total number of the trenches is n, a length of the Si substrate in the predetermined direction is Wₓ [cm], and (n·Wₜ/Wₓ) is an opening ratio α, a ratio tₘ/Wₜ of the tₘ with respect to the Wₜ satisfies a condition of a formula (a) shown below.
$${t}_{m} / {W}_{t} > {ρ}_{m} \cdot {d}_{t} / \{ 2 α ( {R}_{ms} + {ρ}_{s} \cdot {d}_{t} + {R}_{sg} ) - 2 {R}_{mg} \} \qquad ( a )$$

2. The semiconductor device according to claim 1, wherein an n-type impurity of a first type is doped in the drift layer and
a concentration of the n-type impurity of the first type in the drift layer is not less than 4×10¹⁶ cm⁻³ and not more than 1×10¹⁷ cm⁻³.

3. The semiconductor device according to claim 1, wherein the drift layer includes a first drift layer that is disposed on the first principal surface and
a second drift layer that is formed on the first drift layer,
an n-type impurity of a first type is doped in each of the first drift layer and the second drift layer, and
a concentration of the n-type impurity of the first type in the first drift layer is higher than a concentration of the n-type impurity of the first type in the second drift layer.

4. The semiconductor device according to claim 3, wherein the concentration of the n-type impurity of the first type in the first drift layer is not less than 1×10¹⁷ cm⁻³ and not more than 1×10¹⁸ cm⁻³ and
the concentration of the n-type impurity of the first type in the second drift layer is not less than 1×10¹⁶ cm⁻³ and not more than 1×10¹⁷ cm⁻³.

5. The semiconductor device according to claim 2, wherein the n-type impurity of the first type is silicon (Si) or tin (Sn).

6. The semiconductor device according to claim 1, wherein the first principal surface is a (111) plane of the Si substrate.

7. The semiconductor device according to claim 1, wherein an n-type impurity of a second type is doped in the Si substrate and a concentration of the n-type impurity of the second type is not less than 1×10¹⁶ cm⁻³ and not more than 1×10²⁰ cm⁻³.

8. The semiconductor device according to claim 7, wherein the n-type impurity of the second type is phosphorus (P).

9. The semiconductor device according to claim 1, wherein the gallium oxide-based semiconductor layer is constituted of an (Inₓ₁Ga₁₋ₓ₁)₂O₃ (0≤x1<1) layer or an (Alₓ₂Ga₁₋ₓ₂)₂O₃ (0≤x2<1) layer.

10. The semiconductor device according to claim 1, wherein an insulating film is formed in surface layer portions of the Si substrate at the side surface of each trench.

11. The semiconductor device according to claim 1, wherein a film thickness of the Si substrate is not less than 50 μm and not more than 1000 μm and
a film thickness of the drift layer is not less than 1 μm and not more than 100 μm.

12. The semiconductor device according to claim 1, comprising: a second electrode that is in Schottky contact with a surface of the drift layer at an opposite side to the Si substrate side.

13. The semiconductor device according to claim 12, wherein the first electrode includes an ohmic metal that is formed on the side surface and the bottom surface of each trench and is in ohmic contact with the drift layer and a first electrode metal that is laminated on the ohmic metal and
the second electrode includes a Schottky metal that is in Schottky contact with the surface of the drift layer at the opposite side to the Si substrate side and a second electrode metal that is laminated on the Schottky metal.

14. A method for manufacturing a semiconductor device comprising:
a step of forming a drift layer on a first principal surface of an Si substrate that has the first principal surface and a second principal surface at an opposite side thereto;
a step of forming a second electrode that is in Schottky contact with a surface of the drift layer at an opposite side to the substrate side;
a step of forming, by digging in from the second principal surface toward the first principal surface, a plurality of trenches that extend in parallel to each other at equal intervals in a predetermined direction along the second principal surface and reach the drift layer; and
a step of forming, on a side surface and a bottom surface of each trench, a first electrode that is in ohmic contact with the drift layer; and
wherein if a thickness of the Si substrate is dₜ [cm], a resistivity of the Si substrate is ρₛ [Ω·cm], a width of each trench is Wₜ [cm], a thickness of the first electrode formed on the side surface of each trench is tₘ [cm], a resistivity of the first electrode is ρₘ [Ω·cm], an interface resistance between the first electrode and the Si substrate is Rₘₛ [Ω·cm²], an interface resistance between the first electrode and the drift layer is R_{mg} [Ω·cm²], an interface resistance between the Si substrate and the drift layer is R_{sg} [Ω·cm²], a total number of the trenches is n, a length of the Si substrate in the predetermined direction is Wₓ [cm], and (n·Wₜ/Wₓ) is an opening ratio α, a ratio tₘ/Wₜ of the tₘ with respect to the Wₜ satisfies a condition of a formula (a) shown below.
$${t}_{m} / {W}_{t} > {ρ}_{m} \cdot {d}_{t} / \{ 2 α ( {R}_{ms} + {ρ}_{s} \cdot {d}_{t} + {R}_{sg} ) - 2 {R}_{mg} \} \qquad ( a )$$
